(19) United States
(12) Patent Application Publication
(10) Pub. No.: US 2015/0059646 A1
(43) Pub. Date: Mar. 5, 2015

(54) VAPOR-DEPOSITION DEVICE FOR COATING TWO-DIMENSIONAL SUBSTRATES

(71) Applicant: FHR Anlagenbau GmbH, Ottendorf-Okrilla (DE)

(72) Inventors: Reinhard Fendler, Moritzburg (DE); Torsten Winkler, Radeberg (DE); Olaf Gawer, Dresden (DE); Roland König, Markersdorf (DE); Sascha Kreher, Dresden (DE)

(21) Appl. No.: 14/477,500

(22) Filed: Sep. 4, 2014

(30) Foreign Application Priority Data
Sep. 4, 2013 (DE) 10 2013 109 663.8

(51) Int. Cl. C23C 14/54; C23C 14/12; C23C 14/28; C23C 14/56

(52) U.S. Cl. CPC C23C 14/542; C23C 14/562; C23C 14/12; C23C 14/28; C23C 14/564; C23C 14/568; C23C 14/541
USPC 118/718

(57) ABSTRACT

A vapor-deposition device for coating two-dimensional substrates with an organic material. The substrates can be positioned within a vacuum chamber above a process chamber or can be moved past the latter by a transport device. A vaporizer for an organic coating material is arranged within the process chamber and opposite the substrates. The process chamber is delimited laterally by shields which, opposite the substrates, extend as far as a feed device for the coating material. The vaporizer includes the feed device for the coating material and radiant heaters underneath the same. This arrangement can achieve, with a high vaporization rate, good homogeneity of the layer thickness and of the layer stoichiometry.

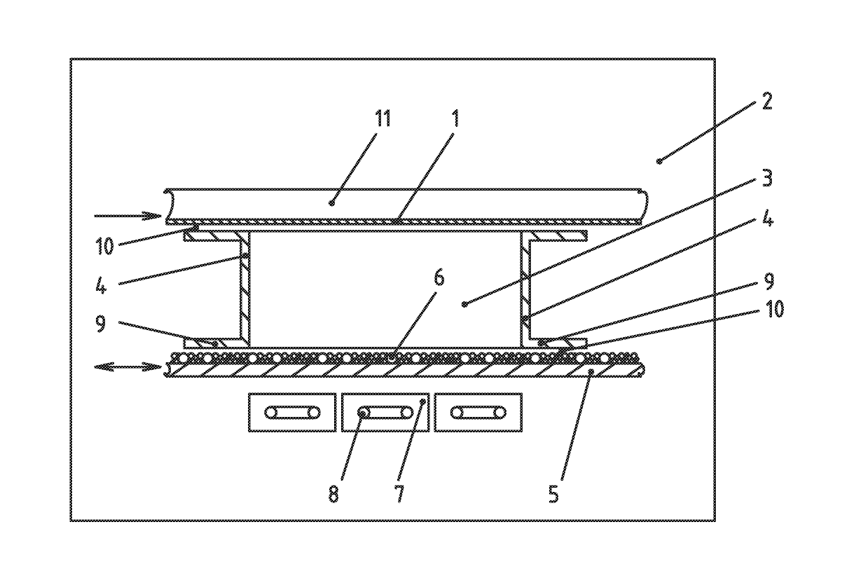

### BACKGROUND

The invention relates to a vapor-deposition device for coating two-dimensional substrates with an organic material, which substrates can be positioned within a vacuum chamber above a process chamber or can be moved past the latter by a transport device, and in which a vaporizer for an organic coating material is arranged within the process chamber and opposite the substrates.

The two-dimensional substrates can be, for example, plates, for example made of glass, plastic or another material, or else strip-like substrates made of plastic or plastic films. Strip-like substrates are usually guided over or through the process chamber in a roll-to-roll process, in each case the side of the substrates to be coated pointing in the direction of the process chamber, i.e. normally downward.

For the coating of the substrates with organic materials, it is necessary to vaporize these materials and to feed them specifically to the surface of the substrate that is to be coated. Since the material vapor is generally removed from the vaporization source at right angles, the surfaces of the substrate that are to be coated are generally arranged or led past opposite the vaporization source. Otherwise, it is necessary to conduct the material vapor specifically to the surface to be coated.

The coating materials used for the production of organic layers have a series of specific properties. For example, some of these materials which, in the initial stage, are generally present as granules or powder in a solid or else in a semi-liquid phase, have the property of sublimating when heated, i.e. they transfer into the vapor phase without previously forming a liquid phase.

If a predefined quantity of coating material to be vaporized is provided, as is the case when supplying a suitable quantity of material for a batch process, it is possible to surmise that, with progressive sublimation, an ever decreasing quantity of material is present, which can be associated with a reduction in the vaporization rate and during which a change in the chemical structure can occur, for example as a result of degeneration. This change in the chemical structure in turn has a detrimental effect on the properties of the vapor-deposited layer.

DE 698 36 039 T2 describes vaporization sources for organic materials, which are accommodated in the lower region of a vacuum chamber, the walls of which simultaneously delimit a process chamber, and wherein a glass substrate to be coated is arranged above the vaporization sources in the vacuum chamber. This is thus a coating system operated in batch mode, in which respectively only one or more substrates are always coated simultaneously.

In the vaporization sources, a powdery coating material is provided, is heated with the aid of a heater and sublimates in the process, by which means the coating material, which is now gaseous or vaporous, is liberated from the vaporization source and condenses on the glass substrates. If a plurality of vaporization sources are used, then different material layers can be deposited one after another, for example in the form of thin layers.

Furthermore, DE 10 2011 084 996 A1 describes an arrangement for coating a substrate with an organic material. Here, the vaporization source used is a tubular vaporization container, in which organic coating material is accommodated. The vaporization container is located in a housing and is provided with an outlet opening for vaporized material, in the form of a linear gap. Also located in the housing are heat sources, such as double-tube quartz heaters, for heating the coating material in the vaporization container.

The substrate to be coated, made of glass or plastic, is transported over the gap in the vaporization container with the side to be coated at the bottom, so that the vaporized coating material can condense on the substrate.

In the coating systems described, the disadvantages described at the beginning can occur, wherein, in particular following the coating of individual or multiple substrates, the coating material in the vaporization source has to be renewed in order to ensure a uniform layer quality.

### SUMMARY

It is an object of the invention to provide a vapor-deposition device for two-dimensional substrates with which, with a high vaporization rate, good homogeneity of the layer thickness and of the layer stoichiometry can be achieved.

In a vapor-deposition device of the type mentioned at the beginning, this object may be achieved using a process chamber that is delimited laterally by shields which, opposite the substrates, extend as far as a feed device for the coating material, and in that the vaporizer comprises the feed device for the coating material and radiant heaters underneath the same.

In at least some embodiments the radiant heaters comprise a plurality of heating elements that can be adjusted separately on the side facing away from the vaporizer, wherein the heating elements can contain quartz heaters or resistance heating elements.

In some implementations of the invention, the feed device can be moved under the process chamber and parallel to the substrate, wherein the coating material is arranged in a distributed manner on the feed device.

The directions of movement of the transport device for the substrate and the feed device for the coating material can be the same or opposite.

In a further embodiment of the invention, the shields delimiting the process chamber laterally consist of a suitable material, for example a metal, and each have folds angled over at right angles under the substrate and above the feed device, with which an improvement of the sealing of the process chamber with respect to the vacuum chamber surrounding the latter is achieved.

Finally, in at least some embodiments, the process chamber is delimited at the top by the substrate and at the bottom by the feed device, wherein the folds each have a predefined spacing from the substrate and from the feed device, so that particularly effective sealing is achieved by the formation of flow channels. In this way, the greatest possible pressure difference between the process chamber and the vacuum chamber surrounding the latter is implemented, in order, with a high vaporization rate in the process chamber, to minimize contamination with vaporized coating material in the rest of the vacuum chamber.

If multiple process chambers are arranged beside one another in a vacuum chamber, the substrates can be coated with different coating materials one after another, by each process chamber being assigned a feed device for coating material.

Finally, above the process chamber it is possible to provide a cooling/temperature-control device which is in thermal contact with the rear side of the substrate.

Therefore, it is possible for temperature control of the substrate to be carried out to a temperature at which a maximum coating rate can be achieved or at which, for example, chemical reactions can take place in the coating, possibly triggered by a gas additionally conducted into the process chamber. By means of the vapor-deposition device, unused coating material can be fed continuously to the process chamber, which means that, during the vaporization, good homogeneity of the layer thickness and also of the layer stoichiometry can be ensured.

### BRIEF DESCRIPTION OF THE DRAWING

An exemplary embodiment of the invention will be explained in more detail below.

The single drawing figure shows a schematic representation of a vapor-deposition device according to the invention having a process chamber in a vacuum chamber.

### DETAILED DESCRIPTION

The vapor-deposition device for coating two-dimensional substrates 1 with an organic material comprises a schematically indicated vacuum chamber 2, in which there is arranged a process chamber 3. The process chamber 3 is delimited laterally with respect to the vacuum chamber 2 by shields 4. The shields 4 can consist of a metal or another suitable material.

The two-dimensional substrate 1 to be coated, for example a strip-like plastic film, is transported continually past above the process chamber 3 by a suitable transport device, not shown according to the drawing, wherein the side of the substrate 1 to be coated is oriented at the bottom toward the process chamber 3.

Alternatively, the two-dimensional substrate 1 can also be positioned stepwise above the process chamber 3 by using a suitable transport device, and the section of the substrate 1 located above the process chamber can be coated, whereupon a further section of the substrate 1 is then positioned above the process chamber 3.

In a corresponding way, it is also possible to operate with rigid two-dimensional substrates to be coated, such as glass plates or the like, in that these are either moved continuously past above the process chamber 3 or in that such a substrate or a section of the same is respectively positioned above the process chamber 3 and coated. If only one section 1 of the substrate is positioned above the process chamber, the coating must then be carried out in a way similar to that in the case of strip-like substrates 1.

The speed of movement of the substrate 1 during the coating, or the duration of the coating in the case of the coating of stationary substrates, depends on the speed of the coating and the thickness of the latter to be achieved.

Underneath the process chamber 3 there is located a vaporizer, which comprises a feed device 5 for organic coating material 6 to be vaporized and associated radiant heaters 7. The feed device 5 can be a belt conveyor, for example, on which the coating material 6 is transported to the process chamber 3. The radiant heaters 7 are arranged underneath the feed device 5 and comprise a plurality of heating elements 8 which are arranged beside one another and which can contain quartz heaters or resistance heating elements.

The feed device 5 under the process chamber 3 is oriented parallel to the direction of movement of the substrates 1 to be coated, that is to say horizontally. The directions of movement of the substrate 1 and of the feed device 5 can be the same or opposite.

With the aid of the feed device 5, the coating material 6 to be vaporized can be fed continuously or else stepwise to the process chamber 3, depending on the manner in which the substrate 1 to be coated is fed in. It is also possible always to transport only a predefined quantity of coating material 5 into the process chamber 3 until the coating has been completed and then to repeat the process after or during the feeding in of the next substrate 1.

Furthermore, the shields 4 delimiting the process chamber 3 each have folds 9 bent over outward at right angles under the substrate 1, i.e. at their upper end according to the drawing, and above the feed device 5, i.e. at the lower end according to the drawing, with which folds an improvement in the sealing of the process chamber 3 with respect to the vacuum chamber 2 surrounding the latter is achieved.

The process chamber 3 is bounded laterally by the shields 4 and is delimited at the top by the substrate 1 and at the bottom by the feed device 5, the folds 9 each having a predefined spacing, as small as possible, from the substrate 1 and from the feed device 5. In this way, particularly effective sealing is ensured by the formation of flow channels 10, by means of which the largest possible pressure difference between the pressure in the process chamber 3 and the pressure in the vacuum chamber 2 surrounding the latter is realized. In this way, even at a high vaporization rate in the process chamber 3, contamination with vaporized coating material 6 in the rest of the vacuum chamber 2 is minimized.

If a plurality of process chambers 3 are arranged beside one another in the vacuum chamber 2, then the substrates 1 can be coated with different coating materials one after another, by each process chamber 3 being assigned a dedicated feed device 5 for coating material.

During the coating of the substrate, the temperature of the latter can also be controlled to an optimal temperature for the coating operation by using a suitable cooling/temperature-control device 11. For this purpose, the cooling/temperature-control device 11 above the process chamber 3 can be in thermal contact with the rear side of the substrate, i.e. the side that is not to be coated.

Here, the temperature of the substrate can be controlled to a temperature at which a maximum coating rate can be achieved or at which, for example, chemical reactions take place in the coating, possibly triggered by a gas additionally conducted into the process chamber.

With the vapor-deposition device described above, good homogeneity of the layer thickness and of the layer stoichiometry is achieved at a high vaporization rate.

Furthermore, in at least some embodiments, the vapor-deposition device can likewise be used without difficulty for continuous or section-by-section coating of strip-like substrates in so-called continuous process systems or, in the case of individual substrates, integrated into so-called cluster systems with corresponding transport devices.

1. A vapor-deposition device for coating two-dimensional substrates with an organic material, which substrates can be positioned within a vacuum chamber above a process chamber or can be moved past the latter by a transport device, and in which a vaporizer for an organic coating material is arranged within the process chamber and opposite the substrates, wherein the process chamber is delimited laterally by shields which, opposite the substrates, extend as far as a feed device for the coating material, and wherein the vaporizer comprises the feed device for the coating material and radiant heaters underneath the same.

2. The vapor-deposition device as claimed in claim 1, wherein the radiant heaters comprise multiple heating elements arranged beside one another.

3. The vapor-deposition device as claimed in claim 2, wherein the heating elements contain quartz heaters or resistance heating elements.

4. The vapor-deposition device as claimed in claim 1, wherein the feed device can be moved under the process chamber and parallel to the substrate, and wherein the coating material is arranged in a distributed manner on the feed device.

5. The vapor-deposition device as claimed in claim 1, wherein the directions of movement of the transport device for the substrate and of the feed device for the coating material are the same or opposite.

6. The vapor-deposition device as claimed in claim 1, wherein the shields delimiting the process chamber laterally consist of a suitable material, such as a metal, or another suitable material and each have folds angled over outward at right angles under the substrate and above the feed device.

7. The vapor-deposition device as claimed in claim 1, wherein the process chamber is delimited at the top by the substrate and at the bottom by the feed device, wherein the folds each have a predefined spacing from the substrate and from the feed device.

8. The vapor-deposition device as claimed in claim 1, wherein multiple process chambers are arranged beside one another in a vacuum chamber.

9. The vapor-deposition device as claimed in claim 8, wherein each process chamber is assigned a feed device for coating material.

10. The vapor-deposition device as claimed in claim 1, wherein a cooling/temperature-control device, which is in thermal contact with the rear side of the substrate, is provided above the process chamber.

11. A vapor-deposition device for coating two-dimensional substrates with an organic material, comprising:
a vacuum chamber having a process chamber and configured to permit the substrates to be positioned within the vacuum chamber above the process chamber or to move past the process chamber;
a vaporizer for an organic coating material located within the process chamber, the vaporizer including a feed device that provides the organic coating material within the process chamber at a location opposite the substrate, the vaporizer having one or more radiant heaters located under the feed device; and
shields located within the vacuum chamber which delimit the process chamber laterally and extend along the feed device.
